(19) United States
(12) Patent Application Publication
(10) Pub. No.: US 2026/0365508 A1
(43) Pub. Date: Nov. 19, 2026

(54) METHOD FOR WELDING SUBSTRATES AND WELDED SUBSTRATES

(71) Applicants: Schott AG, Mainz (DE); SCHOTT Primoceler Oy, Tampere (FI)

(72) Inventors: Jens Ulrich Thomas, Mainz (DE); Antti Määttänen, Tampere (FI); Ville Polojärvi, Tampere (FI); Ossi Lahtinen, Tampere (FI)

(73) Assignees: Schott AG, Mainz (DE); SCHOTT Primoceler Oy, Tampere (FI)

(21) Appl. No.: 19/143,237

(22) PCT Filed: Dec. 18, 2023
(86) PCT No.: PCT/EP2023/086263

§ 371 Date: Jun. 25, 2025

(30) Foreign Application Priority Data
Dec. 28, 2022 (EP) 22216975.7

(51) Int. Cl. B81C 3/00; B23K 26/364; B23K 103/00; B28D 5/00; C03B 23/24

(52) U.S. Cl. CPC B81C 3/001; B23K 26/364; C03B 23/24; B23K 2103/52; B23K 2103/54; B23K 2103/56; B28D 5/0011

(57) ABSTRACT

A method for welding a plurality of substrates includes the steps of: bringing a first substrate and a second substrate in contact with each other such that a contact area between the first substrate and the second substrate is formed; introducing at least two outer weld lines extending next to each other within the contact area into the first substrate and the second substrate such that the first substrate and the second substrate are welded together by each of the at least two outer weld lines and such that a dicing area is defined between the at least two outer weld lines; and introducing at least four inner weld lines extending between the at least two outer weld lines within the dicing area into at least one of the first substrate and the second substrate.

### CROSS REFERENCE TO RELATED APPLICATIONS

This application is a national stage entry under 35 U.S.C. § 371 of International Patent Application No.

PCT/EP2023/086263, entitled “METHOD FOR WELDING SUBSTRATES AND WELDED SUBSTRATES”, filed Dec. 28, 2023, which is incorporated herein by reference. International Patent Application No. PCT/EP2023/086263 claims priority to European Patent Application No. 22216975.7, filed Dec. 28, 2022, which is incorporated herein by reference.

### BACKGROUND OF THE INVENTION

### 1. Field of the Invention

The present invention relates to welds of substrates.

### 2. Description of the Related Art

Singulated chips which are designed as hermetically sealed enclosures may be manufactured in larger numbers in multi-step procedures. For example, two substrates in the form of larger wafers may be brought in contact, wherein functional areas and intermediate areas in between these functional areas are defined. Typically, the stacked substrates are in contact at least in the intermediate areas. The functional areas may for example be designed as cavities holding functional elements or as certain surface regions of the wafers or the like.

Before the stacked substrates are diced into multiple singulated chips, pairs of adjacent weld lines may be introduced within the intermediate areas, each weld line forming a hermetic bond between the two substrates. Dicing of the substrate stack into singulated chips may then take place in between each pair of adjacent weld lines, so that each singulated chip finally retains one surrounding weld line hermetically sealing the functional area of the singulated chip. Various methods may be used to carry out the dicing of such substrate stack.

For example, the substrates may be cut by way of a sawing blade. However, when the sawing blade runs in between the pairs of adjacent weld lines it may happen that the sawing blade occasionally comes into contact with the weld lines which may lead to the impaired hermeticity of the chips and to uneven wear of the sawing blade.

Another exemplary method of dicing may be scribing and subsequent breaking in between the pairs of adjacent weld lines. In this case, however, unclean breaking edges and chipping may occur.

Yet another exemplary method of dicing may be first pre-separating the substrates by introducing laser perforations into the substrate and then etching apart the substrates along the pre-separation lines. In this case, however, etching rates may be irregular or etching fluid may reach the bonding interface. Instead of etching, pre-separation lines may also be separated by breaking which, however, again may lead to unclean breaking edges or chipping.

What is needed in the art is to improve the process of welding substrates and/or processing into singulated chips and the singulated chips themselves, in particular to reduce or avoid the aforementioned problems. An aspect of what is needed in the art is to achieve improved edges of the singulated chips, in particular improved edge-strength. What is also needed in the art is, when dicing is carried out using a sawing blade, to prevent uneven wear of the sawing blade to extend its lifetime. Another aspect of what is needed in the art is, when dicing is carried out by mechanical ways, to achieve more precise breaking edges and avoid chipping. Another aspect of what is needed in the art is, when dicing is carried out by etching, to avoid etching fluid reaching the bonding interface and to achieve more uniform etching rates.

### SUMMARY OF THE INVENTION

The present invention relates to a method for welding substrates, for example glass substrates, by introducing weld lines into the substrates in contact. The invention further relates to welded substrates and to singulated chips, in particular hermetically sealed enclosures. The present invention provides a method for welding substrates wherein a first and a second substrate are brought in contact with each other such that a contact area between the two substrates is formed.

Furthermore, at least two outer weld lines extending next to each other within the contact area are introduced into the first and second substrates such that the first and second substrates are welded together by each of the outer weld lines and such that a dicing area is defined between the two outer weld lines.

Furthermore, four or more inner weld lines are introduced into at least one of the two substrates extending between the two outer weld lines within the dicing area.

The four or more inner weld lines need not necessarily weld together the first and second substrates but may also run within a volume of the substrates. However, it may be preferred that the inner weld lines or at least one or some of them also weld together the first and second substrates as will be explained in more detail later.

The first and a second substrates which are brought in contact with each other may be two individual substrates, for example a top substrate of a substrate stack to be formed and another substrate of the substrate stack to be formed, such as a bottom substrate in case the substrate stack consists of only two substrates, or an inner substrate such as a spacer substrate in case the substrate stack includes more than two substrates.

The first and a second substrates which are brought in contact may also be an individual substrate and an outer substrate of an already existing substrate stack. It may also be the case that both first and a second substrates which are brought in contact are outer substrates of an already existing substrate stack.

Preferably, the first substrate is an integrally formed individual substrate. The second substrate may be an integrally formed individual substrate or an outer substrate of an assembled substrate stack which includes one or more substrates.

In some embodiments of the invention, the method may further include dicing the welded substrates into multiple singulated chips by cutting the welded substrates within the dicing area. Preferably, the cutting may be performed on at least one of the inner weld lines extending within the dicing area.

The inner weld lines within the dicing area have several advantages, which is counterintuitive, because contact or imminent contact with weld lines during dicing is usually not desired. It is particularly surprising that the presence of inner weld lines is beneficial for different processes of dicing, so that the welding of the substrates may even be optimized in view of a later dicing but independent of the specific dicing method that will be used at a later stage. Furthermore, surprisingly, the presence of inner weld lines within the dicing zone is not detrimental for separation, thus the increased processing actually reduces the structural difference of non-intersecting and intersecting zones.

According to one exemplary dicing method, the cutting of the welded substrates may be carried out by way of a sawing blade, wherein preferably the sawing blade seizes at least one of the inner weld lines extending within the dicing area.

In this case, due to the inner weld lines in the dicing area, the sawing blade may wear more evenly. A reason is that not only the outer edges of the sawing blade may come in sporadic contact with the outer weld lines, but due to the presence of inner weld lines, a more uniform wear over the entire width of the sawing blade may result. As will be explained in more detail below, hardened material within the melting region of the weld line may increase the wear of the blade. Counterintuitively, such increased wear of the sawing blade may result in an increased lifetime of the sawing blade because inner weld lines may lead to a more uniform wear of the sawing blade allowing for consistent dicing. Moreover, due to inner weld lines, the sawing blade need not be positioned so accurately in order to keep the separation quality on level.

According to another exemplary dicing method, the cutting of the welded substrates may be carried out by scribing and subsequent breaking.

In this case, as will be explained in more detail below, the inner weld lines in the dicing area may involve heating regions surrounding the melting regions of the weld lines, which enables more precise breaking and prevents chipping.

According to another exemplary dicing method, the cutting of the welded substrates may be carried out by laser perforation in which adjacent perforations are introduced into the substrates and subsequent etching in which an etching fluid is used to connect the adjacent perforations and/or by subsequent application of stress. The latter can be achieved mechanically and/or thermally (e.g. by a CO₂ laser or a gas flame).

In this case, the inner weld lines in the dicing area may again involve heating regions surrounding the melting regions of the weld lines, which leads to more uniform etching rates and/or enables more precise breaking and prevents chipping. Moreover, the inner weld lines may prevent etching fluid reaching the bonding interface.

Generally, irrespective of the dicing method, the presence of inner weld lines in the dicing area may lead to remaining partial weld lines at the separation edge and/or remaining parts of heating or melting regions of weld lines at the separation edge, which may result in increased edge-strength of singulated chips and improved hermeticity.

The cross-section of an outer and/or inner weld line may preferably be characterized by an area of nonlinear absorption, an elongated bubble, preferably starting from the area of nonlinear absorption, a melting region, preferably surrounding the elongated bubble, and/or a heating region, preferably surrounding the elongated bubble and/or the melting region.

As described above, the invention includes that a first and a second substrate are brought in contact such that a contact area between these substrates is formed.

Preferably, the contact area has a width of less than 5 mm, preferably of less than 2 mm, more preferably of less than 1 mm most preferably less than 0.6 mm.

Preferably, the contact area has a width of more than 0.1 mm, preferably of more than 0.4, more preferably of more than 0.6 mm.

For example, the width of the contact area may be in the range of 0.1 mm to 5 mm or in the range of 0.4 mm to 2 mm or in the range of 0.6 mm to 1 mm.

As described above, between the at least two outer weld lines, in particular the two innermost outer weld lines, the dicing area is defined.

Preferably, the dicing area has a width of less than 2 mm, preferably of less than 1 mm, more preferably of less than 0.3 mm.

Preferably, the dicing area has a width of more than 0.05 mm, preferably of more than 0.1 mm, more preferably of more than 0.2 mm.

For example, the width of the dicing area may be in the range of 0.05 mm to 2 mm or in the range of 0.1 mm to 1 mm or in the range of 0.2 mm to 0.3 mm.

As described above, at least one inner weld line is introduced extending along the dicing area and between the two outer weld lines. In some embodiments, more than one inner weld line may be beneficial.

Preferably, at least 2 inner weld lines are introduced, preferably at least 4 inner weld lines are introduced, more preferably at least 8 inner weld lines are introduced.

A distance d between two adjacent inner weld lines may be smaller than 0.3 mm, preferably smaller than 0.15 mm, more preferably smaller than 0.05 mm.

In some embodiments, the inner weld lines may be introduced such that the fraction d/w is smaller than 3, preferably smaller than 2, wherein d is the distance between adjacent inner weld lines and w is the width of the dicing area. The distance d may preferably be the average distance between inner weld lines.

In some embodiments, the method for welding substrates may include defining a minimum shear force Fₘᵢₙ that the welding of the first and second substrates needs to withstand, and introducing a number of outer and/or inner weld lines such as to achieve the defined minimum shear force Fₘᵢₙ.

As described above, at least two outer weld lines extending along the contact area are introduced into the first and second substrates to weld them together. In other words, at least one outer weld line extends on each side of the dicing area. In some embodiments, more than one outer weld line on each side of the dicing area may be beneficial.

Preferably, at least 2 outer weld line may be introduced on each side of the dicing area, preferably at least 3 outer weld lines may be introduced on each side of the dicing area, more preferably at least 4 outer weld lines may be introduced on each side of the dicing area.

A distance d between two adjacent outer weld lines on one side of the dicing area may be smaller than 0.3 mm, preferably smaller than 0.15 mm, more preferably smaller than 0.05 mm.

Generally, the invention relates to a method for welding two substrates, wherein, preferably, at least one of the two substrates may be transparent.

In some embodiments, the first substrate, in particular the individual substrate, may include at least one of the following materials: glass, glass ceramic, borosilicate glass, crystal, sapphire, diamond.

In some embodiments, the second substrate may include at least one of the following materials: glass, glass ceramic, borosilicate glass, crystal, sapphire, diamond, silicon, metal.

The two substrates which are brought into contact may for example be in the form of larger wafers which may be diced into a plurality of singulated chips. For example, wafers may be employed which have a thickness in the range of 0.3 mm to 1 mm and a lateral dimension in the range of 150 mm to 250 mm, wherein such wafers may be round.

In some embodiments, the first and/or second substrate may have a thickness in the range of 0.03 mm to 20 mm, preferably in the range of 0.1 mm to 4 mm, more preferably in the range of 0.2 mm to 2 mm.

In some embodiments, the first and/or second substrate may have a lateral dimension in the range of 30 mm to 1000 mm, preferably in the range of 50 mm to 500 mm.

In some embodiments, a plurality of dicing areas may be introduced into the two substrates. In such cases, the welded substrates may be diced into a plurality of singulated chips.

Preferably, such plurality of dicing areas may define a grid, wherein dicing areas may preferably extend orthogonal with respect to each other.

The invention further discloses a welded substrate including at least a first substrate and a second substrate, wherein the first and second substrates are in contact with each other such that a contact area between the two substrates is formed.

At least two outer weld lines extend next to each other within the contact area within the first and second substrates such that the first and second substrates are welded together by each of the outer weld lines and such that a dicing area is defined between the two outer weld lines.

One or more inner weld lines extend between the two outer weld lines within the dicing area within at least one of the two substrates.

Preferably, one or more functional areas are defined which each are hermetically enclosed by the dicing areas.

The first and a second substrates being in contact may be two individual substrates or may be an individual substrate and an outer substrate of a substrate stack or may be two outer substrates of two substrate stacks. Thus, the welded substrates as described may include further substrates.

For example, the welded substrates may include a third substrate, wherein the second and third substrates are in contact with each other such that a contact area between these two substrates is formed.

At least two outer weld lines may extend next to each other within the contact area within the second and third substrates such that the second and third substrates are welded together by each of the outer weld lines and such that a dicing area is defined between the two outer weld lines.

One or more inner weld lines may extend between the two outer weld lines within this dicing area within at least one of the two substrates.

Preferably, one or more cavities are defined which each are hermetically enclosed by the dicing areas.

Preferably, such cavities may be laterally enclosed by a spacer substrate including one or more cavities extending over the entire thickness of the spacer substrate.

The invention further discloses a singulated chip, in particular a hermetically sealed enclosure, including at least a first substrate and a second substrate, wherein the first and second substrates are in contact with each other and are welded together by weld lines.

A functional area is defined which is hermetically enclosed by weld lines. These weld lines weld together first and second substrates.

At least two further weld lines or partial weld lines may be positioned at the lateral edge of at least one substrate. Such weld lines or partial weld lines may be the result of previously introduced inner weld lines and need not necessarily weld together the first and second substrates but may also run within a volume of the substrates.

The singulated chip may include further substrates. For example, a third substrate, wherein the second and third substrates are in contact with each other and are welded together by weld lines.

A cavity may be defined which is hermetically enclosed by weld lines. These weld lines weld together the substrates. Preferably, such cavity may be laterally enclosed by a spacer substrate including a cavity extending over the entire thickness of the spacer substrate.

At least one weld line or a partial weld line may be positioned at the lateral edge of at least one substrate.

Such weld line or partial weld line may be the result of previously introduced inner weld lines and need not necessarily weld together the substrates but may also run within a volume of the substrates.

### BRIEF DESCRIPTION OF THE DRAWINGS

In what follows, the invention is described in further detail with respect to the figures to illustrate, by way of example, features and advantages of some embodiments of the invention.

FIG. 1: shows a perspective view of a two-wafer stack, wherein pairs of outer weld lines are introduced to weld together the two wafers, and wherein inner weld lines are introduced extending between the pairs of outer weld lines;

FIG. 2: shows an exploded view of a singulated chip manufactured by dicing the welded two wafers shown in FIG. 1;

FIG. 3: shows a partial sectional view of a singulated chip manufactured by dicing the welded two wafers shown in FIG. 1;

FIG. 4: Shows a Perspective View of a Three-wafer Stack, wherein pairs of outer weld lines are introduced to weld together the upper two wafers, and wherein inner weld lines are introduced extending between the pairs of outer weld lines;

FIG. 5: shows an exploded view of a singulated chip manufactured by dicing the welded three wafers shown in FIG. 4;

FIG. 6: shows a partial sectional view of a singulated chip manufactured by dicing the welded two wafers shown in FIG. 4;

FIG. 7: shows a perspective view of a singulated chip manufactured by dicing the welded three wafers shown in FIG. 4;

FIG. 8: shows a sectional view of a singulated chip manufactured by dicing the welded two wafers shown in FIG. 4;

FIG. 9: shows several perspective views to illustrate exemplary steps (a), (b), (c), (d) for the fabrication of singulated chips from initial wafers;

FIG. 10: shows a schematic view of pairs of outer weld lines defining dicing areas, wherein a single inner weld line extends within a dicing area;

FIG. 11: shows a schematic view of pairs of outer weld lines defining dicing areas, wherein multiple inner weld lines extend within a dicing area;

FIG. 12: shows a sectional view of two welded substrates, wherein inner weld lines extend over both substrates;

FIG. 13: shows a sectional view of two welded substrates, wherein inner weld lines extend within the volume of a single substrate;

FIG. 14: shows a sectional view of two welded substrates, wherein the distance between inner weld lines is adjusted to the width of the dicing area;

FIG. 15: shows a sectional view of a weld line;

FIG. 16: shows an image of a first exemplary embodiment of welded substrates;

FIG. 17: shows an image of a second exemplary embodiment of welded substrates;

FIG. 18: shows two images (a), (b) of third exemplary embodiments of welded substrates.

### DETAILED DESCRIPTION OF THE INVENTION

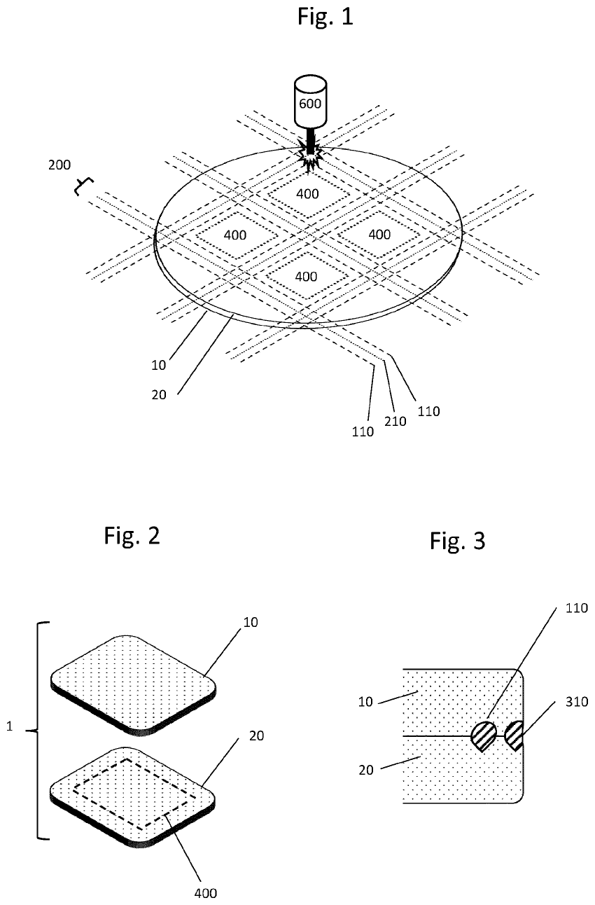

FIG. 1 shows a first substrate 10 in the form of a wafer and a second substrate 20 in the form of a wafer, wherein the substrates 10, 20 are stacked on top of each other. By way of a laser 600, pairs of outer weld lines 110 are introduced into the first and second substrates 10, 20 such that the first and second substrates 10, 20 are welded together. Again, by way of a laser 600, inner weld lines 210 extending between a pair of outer weld lines 110 are introduced into at least one of the two substrates 10, 20. In areas closed all around by weld lines, functional areas 400 are defined.

These functional areas 400 can be singulated by dicing the welded substrates 10, 20 between the functional areas 400 within dicing areas 200 extending between outer weld lines 110. Dicing the welded substrates 10, 20 into multiple singulated chips 1 can be carried out by different cutting methods such as by way of a sawing blade, scribing and subsequent breaking, laser perforation and subsequent etching or subsequent breaking or the like. When cutting the welded substrates along a cutting trench, at least one of the inner weld lines 210 extending within the dicing area 200 may be seized by the cutting method.

FIGS. 2 and 3 show a singulated chip 1 manufactured by dicing the welded two wafers 10, 20. The singulated chip 1 includes a first substrate 10, a second substrate 20 and a functional area 400 which is hermetically enclosed by surrounding weld lines 110, 310, one of which being a partial weld line 310 directly positioned at the lateral edge of the singulated chip 1.

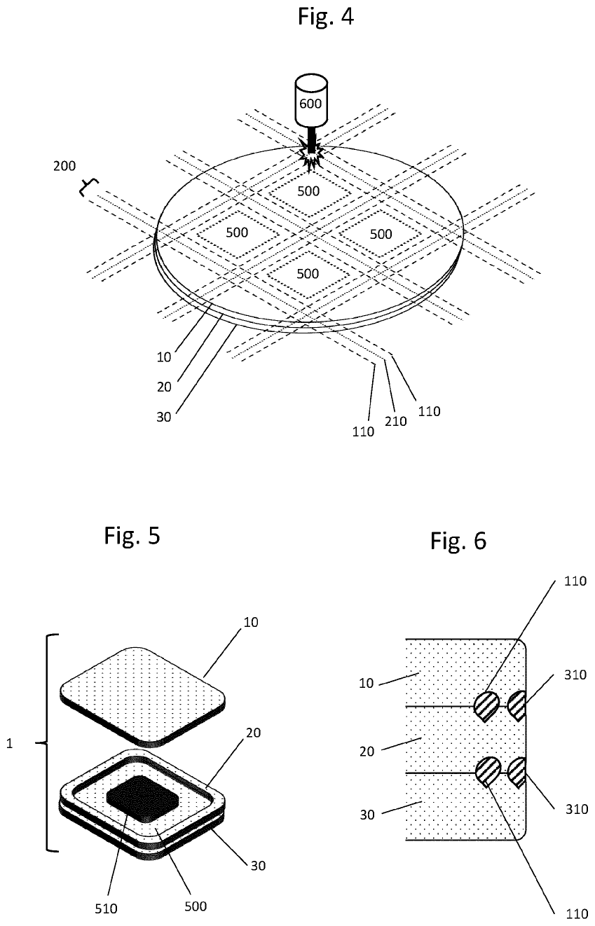

FIG. 4 shows three wafers 10, 20, 30, wherein the lower two wafers 20, 30 are already an assembled wafer stack of two substrates being welded together. The upper wafer 10 is an individual wafer which is brought in contact with the outer wafer 20 of the lower wafer stack. By way of a laser 600, outer weld lines 110 are introduced into the upper individual wafer 10 and the outer wafer 20 of the lower wafer stack so as to weld together the two wafers 10, 20.

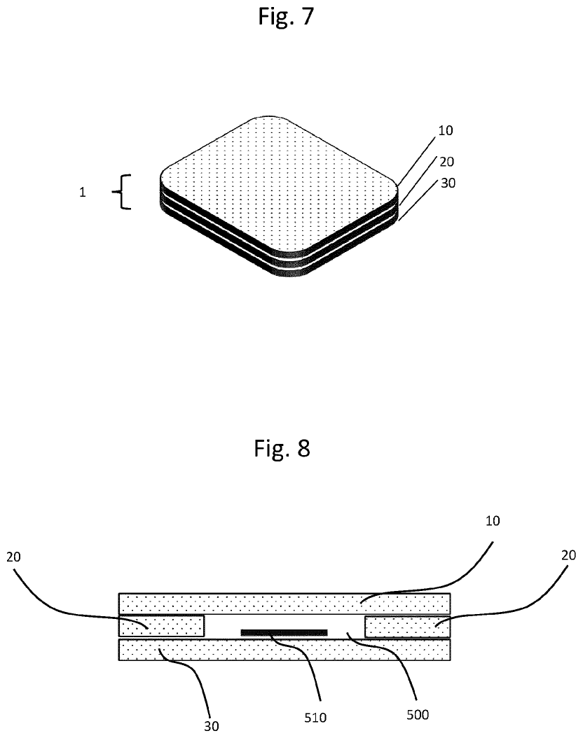

Again, by way of a laser 600, inner weld lines 210 extending between a pair of outer weld lines 110 are introduced into at least one of the two substrates 10, 20. FIGS. 5 to 8 show a singulated chip 1 manufactured by dicing the welded wafer stack 10, 20, 30. The singulated chip 1 includes an upper first substrate 10, an intermediate second substrate 20 and a lower third substrate 30, wherein the intermediate second substrate 20 is a spacer substrate including a cavity 500 extending through the entire thickness of the spacer substrate. The cavity 500 may house a functional element 510, e.g. a microchip. The cavity 500 is hermetically sealed by surrounding weld lines 110, 310 bonding the first and second substrates 10, 20 as well as the second and third substrates 20, 30. At the lateral edge, the singulated chip 1 includes several partial weld lines 310.

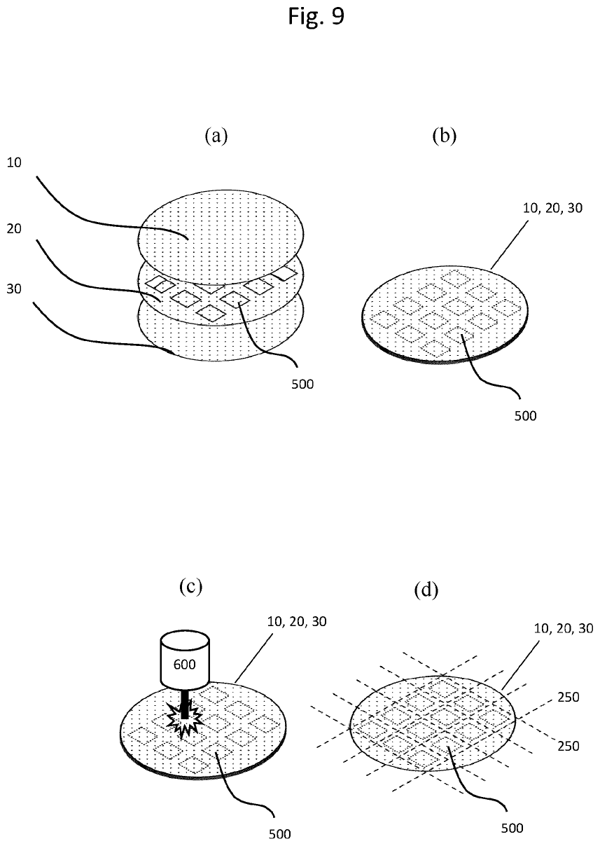

FIG. 9 shows several exemplary steps for the fabrication of singulated chips from initial wafers, in this case three wafers 10, 20, 30. In step (a) some or all of the wafers are aligned with respect to each other and/or with respect to components to be sealed. For example, spacer wafer 20 including cavities 500 may be aligned with respect to functional components attached on lower wafer 30, and upper wafer 10 may be aligned with respect to spacer wafer 20 and/or lower wafer 30. In step (b) the wafers 10, 20, 30 are brought into contact such that contact areas are defined between adjacent wafers, in this case between wafers 10, 20 and between wafers 20, 30. In step (c) adjacent wafers 10, 20 and 20, 30 are welded together by way of a laser 600, wherein weld lines are introduced in the contact area as described further above. In step (d) welded wafer stack 10, 20, 30 may be diced into multiple singulated chips, wherein dicing may be carried out along dicing trenches 250 extending along the contact areas including the weld lines.

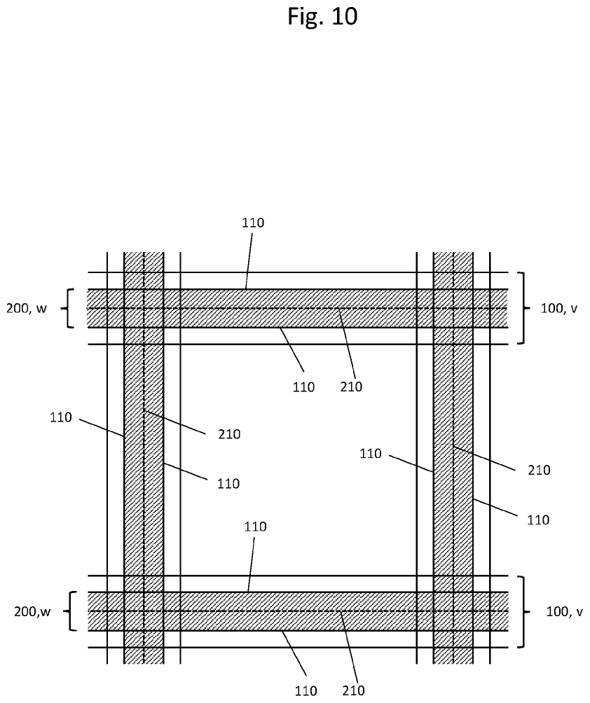

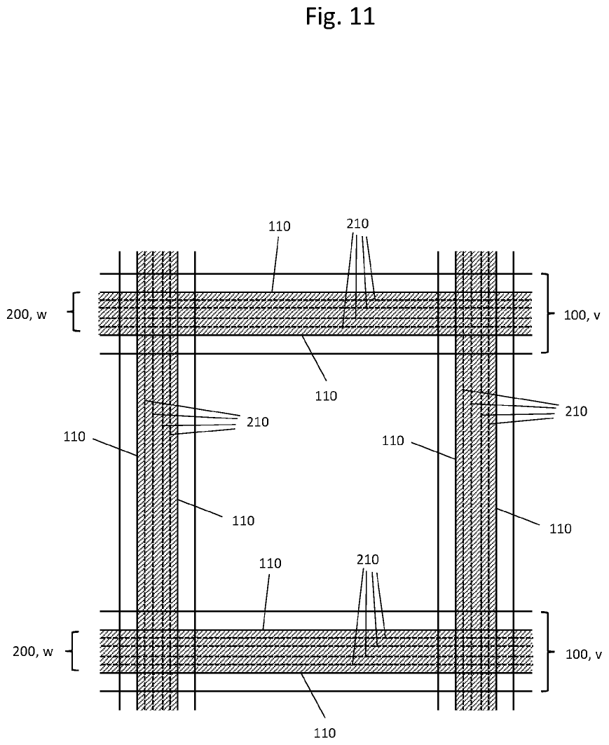

FIGS. 10 and 11 show contact areas 100 between two substrates and pairs of outer weld lines 110 introduced within these contact areas 100, wherein the outer weld lines 110 are the outermost weld lines 110 adjacent to the two edges of the contact area 100. The contact area has a width v. In between these outer weld lines 110 a dicing area 200 is defined which is intended for cutting and dicing the welded substrates, preferably without impairing the outer weld lines 110. The dicing area has a width w, wherein w<=v, preferably w<v. Within the dicing area 200, one or more inner weld lines 210 is introduced, for example one inner weld lines 210 (FIG. 10) or four inner weld lines 210 (FIG. 11). An advantage of less weld lines may be a shorter production time. Preferably, cutting the welded substrates is carried out on one or more inner weld lines 210, so that partial weld lines 310 remain at the edges of the singulated chips 1.

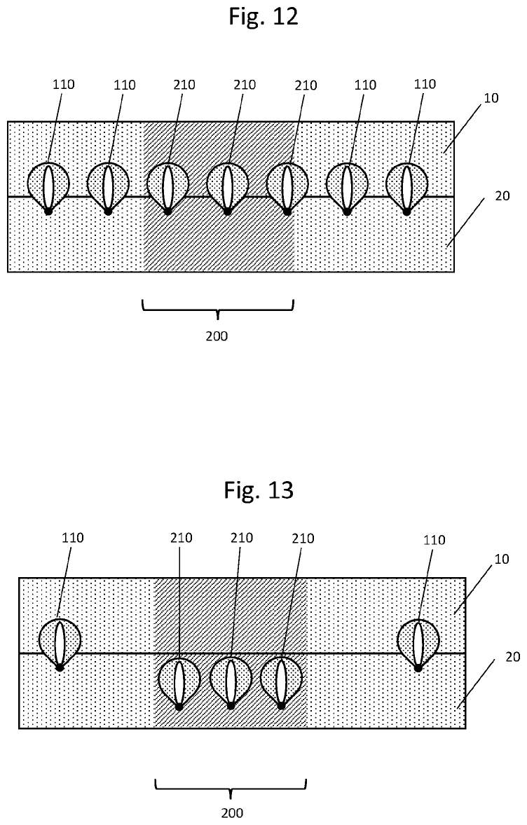

FIG. 12 shows an embodiment of two welded substrates 10, 20, wherein two outer weld lines 110 are introduced on each side of the dicing area 200 and multiple inner weld lines 210 are introduced within the dicing area 200. In this case, inner weld lines 210 are positioned at equal distances and at equal focal positions, i.e., at equal depths within the substrates, relative to the outer weld lines 110. In this case, both the outer weld lines 110 and the inner weld lines 210 are positioned at the interface of the two substrates 10, 20 and thus weld together the two substrates 10, 20.

FIG. 13 shows an embodiment of two welded substrates 10, 20, wherein a single outer weld line 110 is introduced on each side of the dicing area 200 and multiple inner weld lines 210 are introduced within the dicing area 200. In this case, inner weld lines 210 have a greater distance to the outer weld lines 110 than inner weld lines 210 have with respect to each other. Furthermore, inner weld lines are positioned within the volume of one of the substrates, in this case the lower substrate 20. Thus, inner weld lines are not contributing to welding together the two substrates 10, 20. An advantage may be that material in the separation zone is easier to separate from singulated chips, since it falls apart.

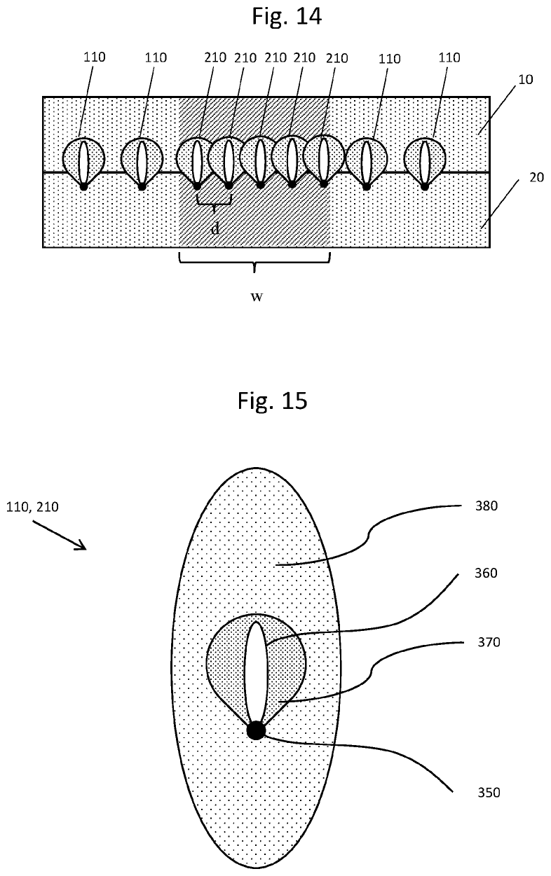

FIG. 14 shows an embodiment of two welded substrates 10, 20, with outer weld lines 110 and inner weld lines 210 introduced in the two substrates. The inner weld lines preferably are introduced such that the fraction d/w is smaller than 3, preferably smaller than 2, wherein d is the distance between adjacent inner weld lines 210 and w is the width of the dicing area 200. As described above, at least one some of the inner weld lines may be in the plane of the outer weld lines and/or may be entirely in the volume of one of the substrates.

FIG. 15 shows a weld line, wherein the weld line includes several regions or areas such as an area of nonlinear absorption 350, an elongated bubble 360, preferably starting from the area of nonlinear absorption, a melting region 370, preferably surrounding the elongated bubble, and/or a heating region 380, preferably surrounding the elongated bubble and/or the melting region.

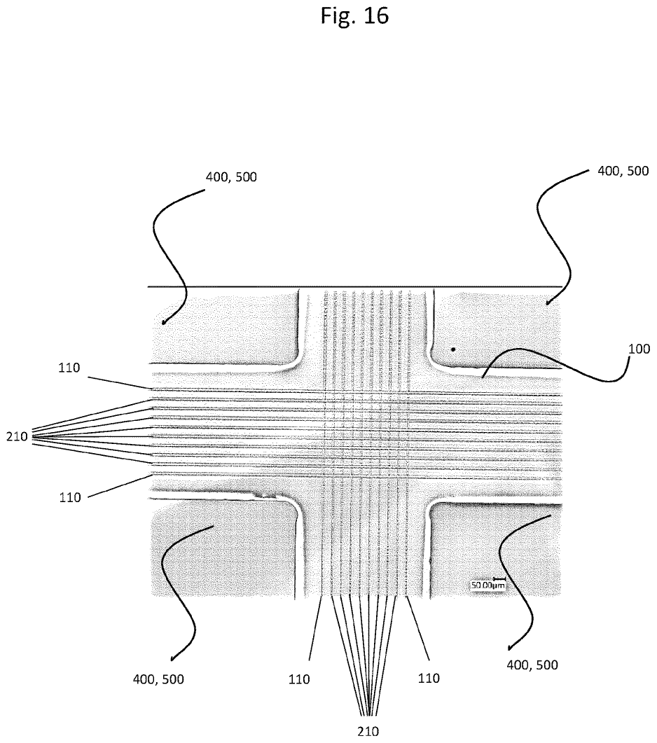

FIG. 16 shows an image of a first exemplary embodiment of welded substrates defining functional areas 400 and/or cavities 500 between contact areas 100 and including several weld lines forming an orthogonal grid. In this case, the weld line pitch is in a range of 20 μm to 60 μm, for example 40 μm. The width of the weld zone is between 250 μm and 450 μm, for example 360 μm.

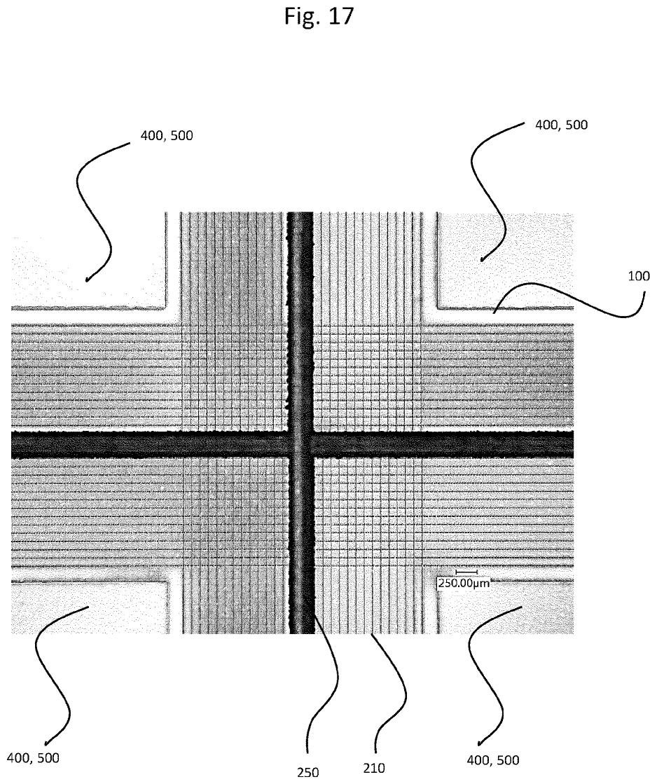

FIG. 17 shows an image of a second exemplary embodiment of welded substrates defining functional areas 400 and/or cavities 500 between contact areas 100 and including several weld lines forming an orthogonal grid. In this case, the weld line pitch is in a range of 20 μm to 200 μm, for example 100 μm. The width of the weld zone is between 50 μm and 5000 μm, for example 3000 μm. The width of a dicing trench 250 is between 150 μm and 450 μm, for example 310 μm.

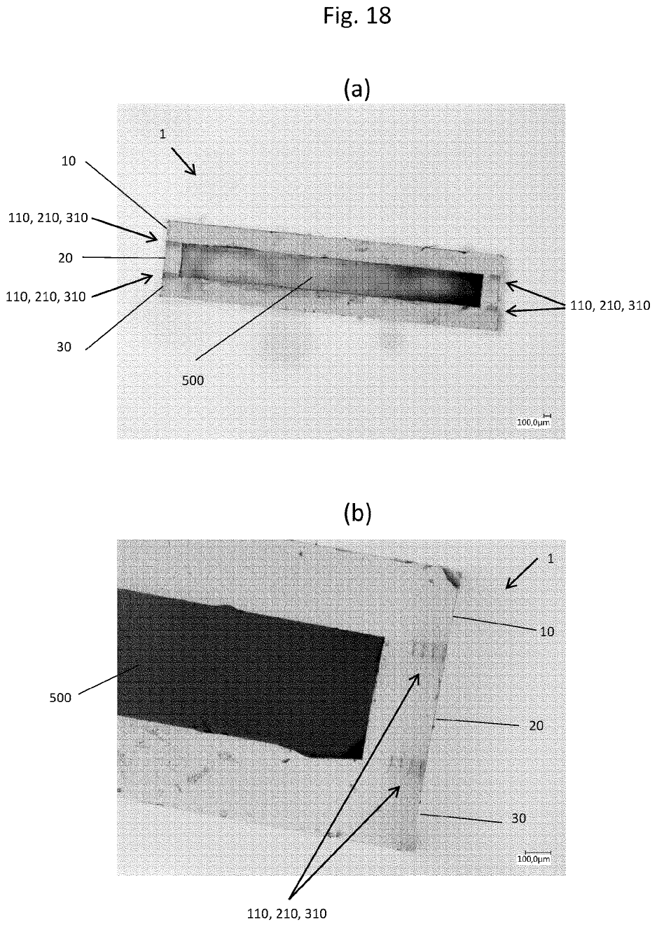

FIG. 18 shows embodiments of a singulated glass enclosure 1. It has been cut in half and polished at the cutting side in order to show the weld lines in the microscope pictures. It includes three substrates 10, 20, 30 welded together by weld lines 110, 210, 310. The substrates, in this case, are made of Borofloat 33™ glass with thicknesses of 320 μm, 500 μm and 320 μm respectively, that enclose a cavity 500. In this case, as in FIG. 16, the weld line pitch is in a range of 20 μm to 60 μm, for example 40 μm. The width of the weld zone is between 250 μm and 450 μm, for example 360 μm. The singulation has been done with a dicing saw.

### LIST OF REFERENCE SIGNS

1 Singulated chip
10 First substrate
20 Second substrate
30 Third substrate
100 Contact area of width v
110 Outer weld line
200 Dicing area of width w
210 Inner weld line
250 Dicing trench
310 Partial weld line
350 Area of nonlinear absorption
360 Elongated bubble
370 Melting region
380 Heating region
400 Functional area
500 Cavity
510 Functional element
600 Laser

1-20. (canceled)

21. A method for welding a plurality of substrates, the method comprising the steps of:
bringing a first substrate and a second substrate in contact with each other such that a contact area between the first substrate and the second substrate is formed;
introducing at least two outer weld lines extending next to each other within the contact area into the first substrate and the second substrate such that the first substrate and the second substrate are welded together by each of the at least two outer weld lines and such that a dicing area is defined between the at least two outer weld lines; and
introducing at least four inner weld lines extending between the at least two outer weld lines within the dicing area into at least one of the first substrate and the second substrate.

22. The method according to claim 21, further comprising the step of dicing the first substrate and the second substrate-which are welded together-into a plurality of singulated chips by cutting the first substrate and the second substrate-which are welded together-within the dicing area.

23. The method according to claim 22, performing the cutting on at least one of the inner weld lines extending within the dicing area.

24. The method according to claim 22, wherein the cutting of the first substrate and the second substrate-which are welded together-is carried out using a sawing blade.

25. The method according to claim 24, wherein the sawing blade seizes at least one of the inner weld lines extending within the dicing area.

26. The method according to claim 22, wherein the cutting of the first substrate and the second substrate-which are welded together-is carried out by scribing and subsequent breaking.

27. The method according to claim 22, wherein the cutting of the first substrate and the second substrate—which are welded together—is carried out by (a) laser perforation in which a plurality of adjacent perforations are introduced into the first substrate and the second substrate and (b) at least one of (i) subsequent etching in which an etching fluid is used to connect the plurality of adjacent perforations and (ii) subsequent application of a stress.

28. The method according to claim 21, wherein a cross-section of at least one of (a) at least one of the outer weld lines and (b) at least one of the inner weld lines includes at least one of the following:
(i) an area of nonlinear absorption;
(ii) an elongated bubble;
(iii) a melting region; and
(iv) a heating region.

29. The method according to claim 21, wherein a cross-section of at least one of (a) at least one of the outer weld lines and (b) at least one of the inner weld lines includes at least one of the following:
(i) an area of nonlinear absorption;
(ii) an elongated bubble, starting from the area of nonlinear absorption;
(iii) a melting region, surrounding the elongated bubble; and
(iv) a heating region, surrounding at least one of the elongated bubble and the melting region.

30. The method according to claim 21, wherein at least one of:
(a) the contact area has a width of less than 5 mm; and
(b) the contact area has a width of more than 0.1 mm.

31. The method according to claim 21, wherein at least one of:
(a) wherein the dicing area has a width of less than 2 mm; and
(b) wherein the dicing area has a width of more than 0.05 mm.

32. The method according to claim 21, wherein at least one of:
(a) at least 8 of the inner weld lines are introduced;
(b) two adjacent ones of the inner weld lines have a distance (d) to each other which is smaller than 0.3 mm; and
(c) the inner weld lines are introduced such that a fraction d/w is smaller than 3, wherein d is a distance between adjacent ones of the inner weld lines and w is the width of the dicing area.

33. The method according to claim 21, further comprising:
defining a minimum shear force Fₘᵢₙ that a welding of the first substrate and the second substrate needs to withstand; and
introducing at least one of a number of the outer weld lines and a number of the inner weld lines so as to achieve the minimum shear force Fₘᵢₙ which is defined.

34. The method according to claim 21, wherein at least one of:
wherein the at least 2 outer weld line are introduced on each side of the dicing area; and
wherein two adjacent ones of the outer weld lines have a distance (d) to each other which is smaller than 0.3 mm.

35. The method according to claim 21, wherein at least one of:
wherein the first substrate includes one of the following materials: glass; glass ceramic;
borosilicate glass; crystal, sapphire; and diamond; and
wherein the second substrate includes one of the following materials: glass; glass ceramic; borosilicate glass; crystal; sapphire; diamond; silicon; and metal.

36. The method according to claim 21, wherein at least one of:
wherein at least one of the first substrate and the second substrate has a thickness in a range of 0.03 mm to 20 mm; and
wherein at least one of the first substrate and the second substrate has a lateral dimension in a range of 30 mm to 1000 mm.

37. The method according to claim 21, wherein a plurality of the dicing area are introduced into the first substrate and the second substrate.

38. An assembly of a plurality of substrates welded together, the assembly comprising:
a first substrate;
a second substrate, the first substrate and the second substrate being in contact with each other such that a contact area between the first substrate and the second substrate is formed;
at least two outer weld lines extending next to each other within the contact area within the first substrate and the second substrate such that the first substrate and the second substrate are welded together by each of the at least two outer weld lines and such that the assembly includes a dicing area which is defined between the at least two outer weld lines; and
at least four inner weld lines extending between the at least two outer weld lines within the dicing area within at least one of the first substrate and the second substrate.

39. The assembly of the plurality of substrates welded together according to claim 38, further comprising at least one functional area and a plurality of the dicing area, wherein the at least one functional area each is hermetically enclosed by the plurality of the dicing area.

40. The assembly of the plurality of substrates welded together according to claim 38, further comprising a third substrate, wherein the contact area is a first contact area, wherein the second substrate and the third substrate are in contact with each other such that a second contact area between the second substrate and the third substrate is formed, wherein the assembly further includes at least two outer weld lines extending next to each other within the second contact area within the second substrate and the third substrate such that the second substrate and the third substrate are welded together by each of the at least two outer weld lines and such that the assembly includes another dicing area which is defined between the at least two outer weld lines, wherein the assembly further includes a plurality of inner weld lines associated with the second substrate and the third substrate such that at least one of the plurality of inner weld lines extends between the at least two outer weld lines associated with the second substrate and the third substrate.

41. A singulated chip, comprising:
a first substrate including a first lateral edge;
a second substrate including a second lateral edge, the first substrate and the second substrate being in contact with each other and being welded together by a plurality of weld lines, the plurality of weld lines including (i) a plurality of outer weld lines and (ii) at least two weld lines or partial weld lines which are positioned at at least one of the first lateral edge and the second lateral edge; and
a functional area which is hermetically enclosed by the plurality of outer weld lines.

42. The singulated chip according to claim 41, further comprising a third substrate including a third lateral edge, the plurality of weld lines being a first plurality weld lines, the second substrate and the third substrate being in contact with each other and being welded together by a second plurality of weld lines, the singulated chip further including a cavity which is defined and is hermetically enclosed by the second plurality of weld lines, the second plurality of weld lines including at least one weld line or a partial weld line which is positioned at at least one of the second lateral edge and the third lateral edge, the singulated chip being a hermetically sealed enclosure.
